(19) United States
(12) Patent Application Publication
(10) Pub. No.: US 2024/0290876 A1
(43) Pub. Date: Aug. 29, 2024

(54) Nitrogen-Polar Group III-Nitride Semiconductor Device with Isolation Implant Regions

(71) Applicant: Wolfspeed, Inc., Durham, NC (US)

(72) Inventors: Kyle Bothe, Cary, NC (US); Chris Hardiman, Cary, NC (US); Scott Sheppard, Chapel Hill, NC (US)

(21) Appl. No.: 18/173,534

(22) Filed: Feb. 23, 2023

(51) Int. Cl. H01L 29/778; H01L 29/16; H01L 29/20; H01L 29/66

(52) U.S. Cl. CPC H01L 29/7786; H01L 29/1608; H01L 29/2003; H01L 29/66462

(57) ABSTRACT

Semiconductor device having nitrogen-polar (N-polar) Group III-nitride structures are provided. In one example, a semiconductor device may include an N-polar Group III-nitride semiconductor structure. The N-polar Group III-nitride semiconductor structure may have a first region and a second region. The N-polar Group III-nitride semiconductor structure may have a first surface and a second surface opposing the first surface. The second surface may be a planar surface. The semiconductor device may include an isolation implant region extending from the second surface into the N-polar Group III-nitride semiconductor structure to a depth sufficient to provide electrical isolation between the first region and the second region of the N-polar Group III-nitride semiconductor structure.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device may include a nitrogen-polar (N-polar) Group III-nitride semiconductor structure. The N-polar Group III-nitride semiconductor structure may have a first region and a second region. The N-polar Group III-nitride semiconductor structure may have a first surface and a second surface opposing the first surface. The second surface may be a planar surface. The semiconductor device may include an isolation implant region extending from the second surface into the N-polar Group III-nitride semiconductor structure to a depth sufficient to provide electrical isolation between the first region and the second region of the N-polar Group III-nitride semiconductor structure.

Another example aspect of the present disclosure is directed to a semiconductor device. The semiconductor device may include an N-polar Group III-nitride semiconductor structure. The N-polar Group III-nitride semiconductor structure may have a first surface and a second surface opposing the first surface. The second surface may be a planar surface. The N-polar Group III-nitride semiconductor structure may include a barrier layer and a channel layer on the barrier layer. The N-polar Group III-nitride semiconductor structure may include a two-dimensional electron gas (2DEG) at an interface between the barrier layer and the channel layer. The semiconductor device may include an isolation implant region extending from the second surface of the N-polar Group III-nitride semiconductor structure at least into the channel layer.

Another example aspect of the present disclosure is directed to a method of forming a semiconductor device. The method may include forming an N-polar Group III-nitride semiconductor structure. The N-polar Group III-nitride semiconductor structure may have a first region and a second region. The N-polar Group III-nitride semiconductor structure may have a first surface and a second surface opposing the first surface. The method may include implanting dopants into the N-polar Group III-nitride semiconductor structure to form an isolation implant region in the semiconductor structure. The isolation implant region extends from the second surface into the N-polar Group III-nitride semiconductor structure to a depth sufficient to provide electrical isolation between the first region and the second region of the N-polar Group III-nitride semiconductor structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts example metal-polar and nitrogen-polar (N-polar) Group-III nitride crystal structures.

FIG. 2 depicts an example semiconductor device according to example embodiments of the present disclosure.

FIG. 3 depicts an example semiconductor device including a plurality of device cells according to example embodiments of the present disclosure;

FIG. 4 depicts a close of an example isolation implant region according to example embodiments of the present disclosure;

FIG. 5 depicts a close of an example isolation implant region according to example embodiments of the present disclosure;

FIG. 6 depicts a close of an example isolation implant region according to example embodiments of the present disclosure; and

FIGS. 7A-7D depict a cross-sectional views illustrating aspects of an example method for forming isolation implant regions in a semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-nitride based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

HEMT devices may include metal-polar (e.g., Ga-polar) or nitrogen-polar (e.g., N-polar) Group III-nitride semiconductor structures. More specifically, Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the Group III-nitride semiconductor structure. A direction associated with the spontaneous polarization dipole may determine whether the Group III-nitride semiconductor structure is metal-polar or N-polar.

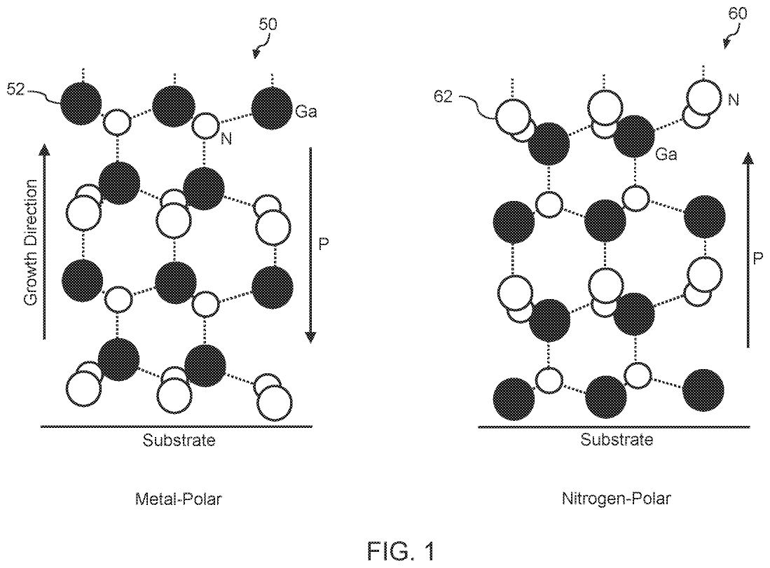

For instance, FIG. 1 depicts an example metal-polar Group III nitride semiconductor structure 50 (e.g., Ga-polar GaN) and an example N-polar Group III-nitride semiconductor structure 60 (e.g., N-polar GaN). As shown, the metal-polar Group III-nitride semiconductor structure 50 and the N-polar Group III-nitride semiconductor structure 60 each have a hexagonal wurtzite crystal structure. In a wurtzite crystal structure, the metal (e.g., gallium) and the nitrogen are arranged in separate distinct layers. The metal-polar (e.g., Ga-polar) Group III-nitride semiconductor structure 50 has a metal face 52 (e.g., gallium face) in the growth direction of the semiconductor structure 50 relative to a substrate. The direction of the spontaneous polarization dipole P may be opposite the growth direction in the metal-polar Group III-nitride semiconductor structure 50. The N-polar semiconductor structure 60 has a nitrogen face 62 in the growth direction of the semiconductor structure 60 relative to a substrate. The direction of the spontaneous polarization dipole P may be the same as the growth direction in the N-polar Group III-nitride semiconductor structure 60. HEMT devices including N-polar Group III-nitride structures have recently been shown to deliver significant performance advantages, particularly at operating frequencies in the millimeter wave frequency ranges (e.g., 30 GHz or greater) relative to traditional metal-polar Group-III nitride structures.

It may be desirable to provide electrical isolation between semiconductor device cells in a semiconductor device to prevent and/or reduce electrical conduction between device cells (e.g. HEMT device cells). In some instances, electrical isolation has been provided between device cells in N-polar Group III-nitride based devices by etching and removing conducting layers between the device cells. This may lead to various issues, including providing non-planar devices that may not be ideal for any subsequent lithography processing. Moreover, etching N-polar Group III-nitride structures may lead to sidewall exposure of the N-polar Group III-nitride structure, which may cause higher dispersion of the semiconductor device due to, for instance, trapping effects.

Aspects of the present disclosure are directed to semiconductor devices having an N-polar Group III-nitride structure. Isolation implant region(s) may be provided in the semiconductor devices to electrically isolate differing regions (e.g., regions associated with different device cells) in the Group III-nitride semiconductor structure. More specifically, in some examples, an isolation implant region may be formed in the semiconductor structure using an implantation process. The isolation implant region may extend through the semiconductor structure to a depth sufficient to provide electrical isolation between regions in the Group III-nitride semiconductor. For instance, the isolation implant region may extend to a depth of about 500 Angstroms or greater, such as about 750 Angstroms or greater, such as in a range of about 500 Angstroms to about 5 microns, such as about 1000 Angstroms to about 2 microns, such as about 1000 Angstroms to about 2500 Angstroms.

In some examples, the isolation implant region may extend into a buffer layer associated with the N-polar Group III-nitride semiconductor structure. The buffer layer may be iron doped such that it is semi-insulating. In some examples, the isolation implant region may extend into a barrier layer (e.g., a back barrier layer) associated with the N-polar Group III-nitride semiconductor structure.

In some examples, the isolation implant region may extend through the N-polar Group III-nitride semiconductor structure to an interface between the N-polar Group III-nitride semiconductor structure and a substrate, such as the substrate on which the N-polar Group III-nitride was formed or placed, such as a silicon carbide substrate. In some examples, the isolation implant region may extend at least partially into the substrate. In these examples, it may not be necessary to have a semi-insulating buffer layer and the buffer layer may be undoped or only unintentionally doped.

The isolation implant region may have a distribution of dopants. The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³.

The distribution of dopants may have a distribution profile. In some examples, the distribution profile may be nearly uniform at all depths of the isolation implant region. In some examples, the distribution profile may have one or more peak regions where there is an increased dopant concentration relative to other regions in the isolation implant region. In some examples, the peak dopant concentration may be located in the isolation implant region at a region near an interface between a barrier layer and a channel layer in the N-polar Group III-nitride semiconductor structure (e.g., near a 2DEG of an HEMT device). In some examples, the peak dopant concentration may be located at a location buried deep within the semiconductor structure, such as at a depth in a range of about 500 Angstroms to about 1750 Angstroms beneath a surface of the semiconductor structure, such as in a range of about 750 Angstroms to about 1500 Angstroms beneath a surface of the semiconductor structure.

In some examples, the semiconductor device may be a transistor device. The transistor device may be an HEMT device having an N-polar Group III-nitride semiconductor structure despised on a substrate, such as a silicon carbide substrate. The N-polar Group III-nitride semiconductor structure may have an N-face in the growth direction of the N-polar Group III-nitride semiconductor structure.

The N-polar Group III-nitride semiconductor structure may include a channel layer that is deeply buried beneath the top surface of the semiconductor structure, such as at a depth of about 275 Angstroms or greater, such as about 500 Angstroms or greater, such as in a range of about 275 Angstroms to about 1000 Angstroms. The channel layer may be, for instance, a GaN layer. The channel layer may be on a barrier layer (e.g., back barrier layer). The barrier layer may have a different band gap than the band gap of the channel layer. The barrier layer may be, for instance, an AlGaN layer or a multilayer structure including an AlGaN layer. A 2DEG may be formed at an interface between the channel layer and the barrier layer such that the 2DEG is also buried deeply within the semiconductor structure.

The N-polar Group III-nitride semiconductor structure may include a buffer layer. The back barrier layer may be on the buffer layer such that the back barrier layer is between the buffer layer and the channel layer. In some examples, the buffer layer may be a GaN layer, such as an iron doped layer to make the buffer layer semi-insulating. In some examples, the buffer layer may be undoped or may only be unintentionally doped.

The N-polar Group III-nitride semiconductor structure may include one or more cap layers. For instance, the N-polar Group III-nitride semiconductor structure may include a first cap layer on the channel layer. The first cap layer may have a different band gap than the band gap of the channel layer. The first cap layer may be, for instance, an AlGaN layer. The N-polar Group III-nitride may include a second cap layer on the first cap layer. The second cap layer may be, for instance, a GaN layer. The second cap layer may have a thickness, for instance, in a range of about 250 Angstroms to about 1000 Angstroms.

The second cap layer in transistor devices including an N-polar Group III-nitride semiconductor structure may bury the channel layer and the 2DEG for the transistor device deep below the surface of the semiconductor structure. By burying the channel layer and 2DEG deep below the surface of the semiconductor structure, trapping and other surface effects on the 2DEG may be mitigated by physically moving the 2DEG a larger distance away from the surface of the semiconductor structure. In addition, the increased thickness of the second cap layer may provide for increased polarization of the semiconductor structure at the interface between the channel layer and the back barrier layer. The back barrier layer may be modified to control the channel layer charge density independent of the gate-to-channel layer distance. The second cap layer for N-polar Group III-nitride semiconductor materials may provide for increased charge at the interface between the channel layer and the first confining layer, increasing carrier concentration and electron mobility of the 2DEG. This may lead to enhanced transconductance of the 2DEG and improved performance of the transistor device. For instance, the increased transconductance may provide for a lower on-resistance of the transistor device as well as suitability for use at higher frequencies, such as mm-wave frequencies or higher.

According to example aspects of the present disclosure, the transistor device may include an isolation implant region that extends deep into the surface of the semiconductor structure to provide electrical isolation of conductive layers (e.g., the channel layer) between different regions (e.g., regions associated with different transistor device cells) of the semiconductor structure. For instance, in some examples, the isolation implant region may extend at least into the channel layer. In some examples, the isolation implant region may extend into back barrier layer. In some examples, the isolation implant region may extend into the buffer layer. In some examples, the isolation implant region may extend all the way through the N-polar Group III-nitride semiconductor structure, such as to an interface between a substrate and the N-polar Group III-nitride semiconductor structure. In some examples, the isolation implant region may extend into the substrate.

Some examples of the present disclosure are directed to a method of fabrication of a semiconductor device, such as a transistor device having an N-polar Group III-nitride semiconductor structure. The method may include, for instance, forming a semiconductor structure (e.g., using epitaxial growth) on a substrate. The semiconductor structure may be an N-polar Group III-nitride semiconductor structure. The semiconductor structure may have a first region (e.g., a first device cell) and a second region (e.g., a second device cell).

The method may include implanting dopants (e.g., using an implantation process) to form an isolation implant region in the semiconductor structure. The isolation implant region may extend from the surface of the semiconductor structure to a depth sufficient to provide electrical isolation between the first region and the second region of the semiconductor structure.

For instance, the implant conditions may be selected such that the isolation implant region extends to a depth of about 500 Angstroms or greater, such as about 750 Angstroms or greater, such as in a range of about 500 Angstroms to about 5 microns, such as about 1000 Angstroms to about 2 microns, such as about 1000 Angstroms to about 2500 Angstroms. In some examples, the isolation implant region may extend into a buffer layer associated with the N-polar Group III-nitride semiconductor structure. In some examples, the isolation implant region may extend into a barrier layer (e.g., a back barrier layer) associated with the N-polar Group III-nitride semiconductor structure.

In some examples, the isolation implant region may extend through the N-polar Group III-nitride semiconductor structure to an interface between the N-polar Group III-nitride semiconductor structure and a substrate, such as the substrate on which the N-polar Group III-nitride was formed or placed, such as a silicon carbide substrate. In some examples, the isolation implant region may extend at least partially into the substrate.

In some examples, the implant conditions may be selected such that the distribution of dopants may have a peak dopant concentration of at least about 1×10¹⁸ dopants/cm³. The peak dopant concentration may be located in the isolation implant region at a location within about 250 Angstroms or less of an interface between a barrier layer and a channel layer in the N-polar Group III-nitride semiconductor structure. The dopants may include one or more of nitrogen, hydrogen, zirconium, magnesium, and/or oxygen.

Aspects of the present disclosure provide a number of technical effects and benefits. For instance, electrical isolation may be provided between regions of in an N-polar Group III-nitride semiconductor structure without requiring etching of the N-polar Group III-nitride semiconductor structure. This can preserve a planar surface of the N-polar Group III-nitride semiconductor structure, which can be more suitable for high performance in high frequency and higher power RF applications of the transistor device (e.g., about 30 GHz or greater). Moreover, damage or other defects associated with etching of the N-polar Group III-nitride semiconductor structure may be reduced. In addition, performance degradation due to sidewall exposure of the N-polar Group III-nitride structure resulting from etch processes may be reduced.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims. With reference now to the Figures, example embodiments of the present disclosure will now be set forth.

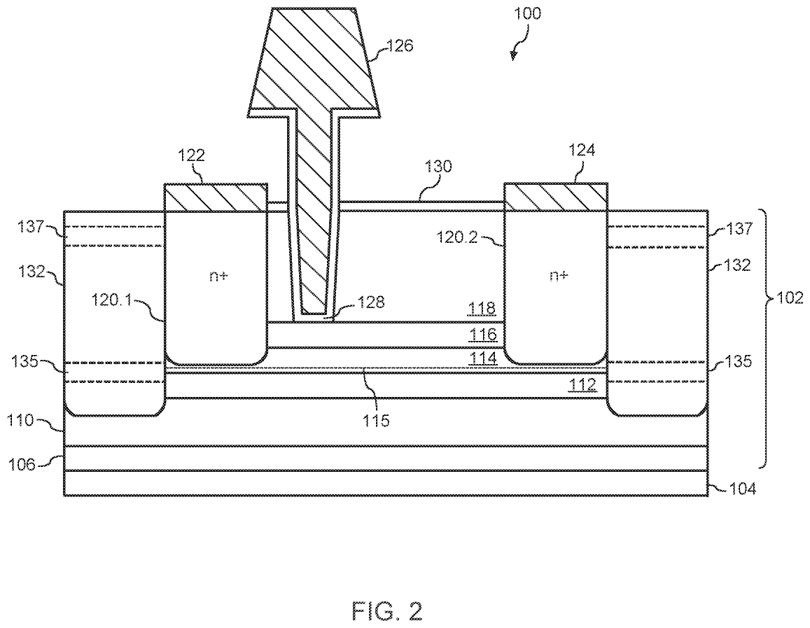

FIG. 2 depicts a cross-sectional view of an example HEMT device 100 according to example embodiments of the present disclosure. FIG. 2 is intended to represent structures for identification and description and is not intended to represent the structures to physical scale. The HEMT device 100 may include a semiconductor structure 102. The semiconductor structure 102 may be a Group III-nitride semiconductor structure, such as an N-polar Group III-nitride semiconductor structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100. In some embodiments, the substrate 104 of the HEMT device 100 may be a thinned substrate 104. In some embodiments, the thickness of the substrate 104 may be about 100 μm or less, such as about 75 μm or less, such as about 50 μm or less.

The semiconductor structure 102 may include an optional nucleation layer 106 on the substrate 104. The nucleation layer 106 may be, for instance, a GaN layer and/or an AlN layer on the substrate 104 to provide a crystal structure transition between, for instance, a SiC substrate 104 and the Group III-nitride semiconductor structure 102. The nucleation layer 106 may be deposited on the substrate 104 using, for instance, metal-organic chemical vapor deposition (MOCVD), molecular beam epitaxy (MBE), or hydride vapor phase epitaxy (HVPE).

The semiconductor structure 102 may be an N-polar Group III-nitride semiconductor structure with an outward N-face in the growth direction 108 of the semiconductor structure 102. The semiconductor structure 102 may include several layers. In the example HEMT device 100 of FIG. 2, the semiconductor structure includes a buffer layer 110, a back barrier layer 112, a channel layer 114, a first cap layer 116, and a second cap layer 118. However, those of ordinary skill in the art, using the disclosures provided herein, will understand that aspects of the present disclosure are applicable to devices having semiconductor structures with different layer arrangements. The semiconductor structure 102 may be formed by epitaxial growth on the substrate 104. Techniques for epitaxial growth of Group III-nitrides have been described in, for example, U.S. Pat. Nos. 5,210,051, 5,393,993, and 5,523,589, the disclosures of which are incorporated by reference herein.

The buffer layer 110 may be an N-polar Group III nitride, such as AlᵥGa₁₋ᵥN, where 0≤v<0.1. In some embodiments, the aluminum mole fraction v is approximately 0 (e.g., 0.05 or less), indicating that the buffer layer 110 is GaN. The buffer layer 110 may or may not include other Group III-nitrides such as InGaN, AlInGaN or the like. The buffer layer 110 may be undoped or only unintentionally doped. In some examples, the buffer layer 110 may be iron doped to make the buffer layer semi-insulating. The buffer layer 110 may be grown to a thickness in the range of about 0.5 μm to about 5 μm, such as about 2 μm. The buffer layer 110 may be a multi-layer structure, such as a superlattice or combinations of GaN, AlGaN or the like. The buffer layer 110 may be under compressive strain in some embodiments.

The semiconductor structure 102 may include the back barrier layer 112 on the buffer layer 110. The back barrier layer 112 may be an N-polar Group III nitride, such as Al_{w}Ga_{1-w}N where 0.1≤w<0.4, indicating that the back barrier layer 112 is an AlGaN layer. In some embodiments, the back barrier layer 112 may be a ScAlN layer or a ScAlGaN layer. The back barrier layer 112 may or may not include other Group III-nitrides such as InGaN, AlInGaN or the like. The back barrier layer 112 may have a different band gap relative to the channel layer 114. The back barrier layer 112 may have a thickness in a range of about 250 Angstroms to about 350 Angstroms, such as about 300 Angstroms.

In some embodiments, the back barrier layer 112 may be a multilayer structure. For instance, in one example, the back barrier layer 112 may include a first layer of n+ doped GaN with a thickness of about 100 Angstroms. The back barrier layer 112 may include a second layer of graded Al_{w·1}Ga_{1-w·1}N on the first layer, where w·1 varies from about 0.05 to about 0.4. The second layer of graded Al_{w}Ga_{1-w}N may have a thickness of about 100 Angstroms. The back barrier layer 112 may include a third layer of Al_{w·2}Ga_{1-w·2}N on the second layer, where w·2 is in a range of 0.3 to 0.4. The thickness of the third layer may be about 100 Angstroms. The back barrier layer 112 may include a fourth layer of AlN on the third layer. The thickness of the fourth layer may be in a range of about 5 Angstroms to about 15 Angstroms, such as about 7 Angstroms.

The semiconductor structure 102 may include the channel layer 114 on the back barrier layer 112. The channel layer 114 may be an N-polar Group III-nitride, such as AlₓGa₁₋ₓN, where 0≤x<0.1, provided that the energy of the conduction band edge of the channel layer 114 is less than the energy of the conduction band edge of the back barrier layer 112 at the interface between the channel layer 114 and the back barrier layer 112. The channel layer 114 may have a band gap that is different than the band gap of the back barrier layer 112. In some embodiments, the aluminum mole fraction x is approximately 0 (e.g., 0.05 or less), indicating that the channel layer 114 is GaN. The channel layer 114 may or may not include other Group III-nitrides such as InGaN, AlInGaN or the like. The channel layer 114 may have a thickness in a range of about 75 Angstroms to about 125 Angstroms, such as about 100 Angstroms.

A 2DEG 115 may be induced in the channel layer 114 at the interface between the channel layer 114 and the back barrier layer 112. The 2DEG 115 is highly conductive and allows conduction between the source and drain regions of the HEMT device 100. The 2DEG 115 may be controlled under operation of a gate, such that the HEMT device 100 acts as a controllable transistor device.

The semiconductor structure 102 includes a first cap layer 116 (e.g., an AlGaN cap layer) on the channel layer 114. The first cap layer 116 may be an N-polar Group III-nitride, such as Al_{y}Ga_{1-y}N where 0.1≤y<0.4, indicating that the first cap layer 116 is an AlGaN layer. In some embodiments, the aluminum mole fraction y is in a range of about 0.2 to about 0.3. In some embodiments, the first cap layer 116 may be a ScAlN layer or a ScAlGaN layer. The first cap layer 116 may or may not include other Group III-nitrides such as InGaN, AlInGaN or the like. The first cap layer may have a band gap that is different than the band gap of the channel layer 114. The first cap layer 116 may have a thickness in a range of about 15 Angstroms to about 50 Angstroms, such as about 26 Angstroms.

The semiconductor structure 102 includes a second cap layer 118 on the first confining layer 116. The second cap layer 118 may be an N-polar Group III-nitride, such as Al_{z}Ga_{1-z}N, where 0≤z<0.1. In some embodiments, the aluminum mole fraction z is approximately 0 (e.g., 0.05 or less), indicating that the second cap layer 118 is a GaN layer. The second cap layer 118 may or may not include other Group III-nitrides such as InGaN, AlInGaN or the like. The second cap layer 118 buries the channel layer 114 deep below the surface of semiconductor structure 102 such that the channel layer 114 is a buried layer at a depth of about 275 Angstroms or greater from the surface of the semiconductor structure 102, such as about 500 Angstroms or greater from the surface of the semiconductor structure 102, such as in a range of about 275 Angstroms to about 1000 Angstroms from the surface of the semiconductor structure 102. The second cap layer 118 may have a thickness in a range of about 250 Angstroms to about 1000 Angstroms, such as about 500 Angstroms.

The semiconductor structure 102 includes implanted regions 120.1 and 120.2. The implanted regions 120.1 and 120.2 include a distribution of implanted dopants (e.g., ions) of a first conductivity type such that the implanted regions 120.1 and 120.2 are n-type regions. The implanted regions 120.1 and 120.2 extend through the semiconductor structure 102 and into the channel layer 114.

The HEMT device 100 includes electrodes on the implanted regions 120.1 and 120.2. More particularly, the HEMT device 100 may include a source contact 122 on the implanted region 120.1. The HEMT device 100 may include a drain contact 124 on the implanted region 120.2. The source contact 122 and the drain contact 124 may be laterally spaced apart from each other. In some embodiments, the source contact 122 and the drain contact 124 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSix, titanium silicide (TiSi), titanium nitride (TiN), tungsten silicon nitride (WSiN), platinum (Pt) and the like. In some embodiments, the source contact 122 may be an ohmic contact. The drain contact 124 may be an ohmic contact. In some embodiments, the source contact 122 and/or the drain contact 124 may include a plurality of layers to form an ohmic contact that may be provided as described, for example, in U.S. Pat. Nos. 8,563,372 and 9,214,352, the disclosures of which are incorporated by reference herein.

The HEMT device 100 may include a gate contact 126. The gate contact 126 may extend at least partially through a trench (e.g., an ALE defined trench) in the cap layer 118 so that the gate contact 126 is proximate to the first cap layer 116. In some examples, the gate contact 126 may have a gate length LG in a range of about 50 nm to about 150 nm. The gate length is the length of the gate contact 126 proximate to the first cap layer 116.

A passivation layer 128 may be located between the gate contact 126 and the first cap layer 116. The passivation layer 128 may be SiN. Other suitable dielectric layers may be used as the passivation layer 128, such as SiO₂, MgOx, MgNx, ZnO, SiNx, SiOx or other dielectric layers. The passivation layer 128 may be formed, for instance, using MOCVD process(s), atomic layer deposition (ALD) process(s), and/or sputter deposition processes. The passivation layer 128 may serve as a gate dielectric. In some examples, the passivation layer 128 may have a thickness, for instance, of about 5 Angstroms to about 100 Angstroms, such as about 10 Angstroms to about 50 Angstroms.

The gate contact 126 may be a T-shaped gate or a gamma gate, the formation of which is discussed by way of example in U.S. Pat. Nos. 8,049,252, 7,045,404, and 8,120,064, the disclosures of which are incorporated by reference herein. Materials capable of making a contact (e.g., a Schottky contact) to a Group III-nitride based semiconductor material may be used, such as, for example, nickel (Ni), platinum (Pt), nickel silicide (NiSix), copper (Cu), palladium (Pd), chromium (Cr), tungsten (W) and/or tungsten silicon nitride (WSiN).

The HEMT device 100 may include additional passivation layer(s) 130 on the semiconductor structure 102, the gate contact 126, and/or other structures of the HEMT device 100. The additional passivation layer(s) 130 may be, for instance, dielectric materials, such as SiO₂, MgOx, MgNx, ZnO, SiNx, SiOx, alloys or layer sequences thereof. The additional passivation layer(s) 130 may be formed using MOCVD process(s), ALD process(s), sputter deposition process(s), or other suitable process(s). One or more insulating layers (not shown) may be on the HEMT device 100. For instance, the HEMT device 100 may be encapsulated in an insulating material without deviating from the scope of the present disclosure.

In some examples, the HEMT device 100 may be operable at frequencies of up to about 150 GHz. For instance, the HEMT device 100 may be operable at a frequency in a range of about 10 GHz to about 150 GHz, such as in a range of about 30 GHz to about 150 GHz, such as in a range of about 50 GHz to about 150 GHz. In some examples, the HEMT device 100 may have a power density of up to 10 W/mm or greater in these frequency ranges, such as a power density in a range of 2.5 W/mm to about 12 W/mm.

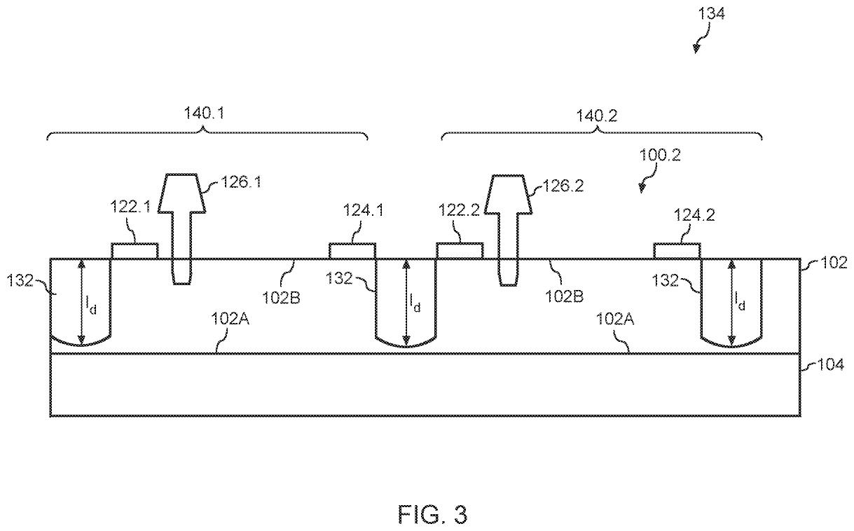

A transistor device cell may be formed by the active region between the source contact 122 and the drain contact 124 under the control of a gate contact 126 between the source contact 122 and the drain contact 124. FIG. 2 depicts a cross-sectional view of one device cell of an HEMT device 100 for purposes of illustration. As will be discussed with reference to FIG. 3, below, the HEMT device 100 may be formed adjacent to additional HEMT device cells.

According to example aspects of the present disclosure, the HEMT device 100 may include an isolation implant region 132. The isolation implant region 132 may extend to a depth in the semiconductor structure 102 sufficient to provide electrical isolation between regions in a semiconductor device, such as a first region associated with a first transistor device cell (e.g., HEMT device cell) and a second region associated with a second transistor device cell (e.g., HEMT device cell).

More specifically, FIG. 3 depicts an example semiconductor device having multiple device cells (e.g., transistor device cells) according to example embodiments of the present disclosure. More particularly, FIG. 3 depicts an example semiconductor device 134 having a first region 140.1 and a second region 140.2. The first region 140.1 may be associated with a first transistor device cell 100.1. The second region 140.2 may be associated with a second transistor device cell 100.2. Each of the transistor device cells 100.1, 100.2 may have a similar configuration as the HEMT device 100 of FIG. 2. FIG. 3 depicts two transistor device cells 100.1, 100.2 for purposes of illustration and discussion. Those of ordinary skill in the art, using the disclosures provided herein, will understand that the semiconductor device 134 may include more transistor device cells without deviating from the scope of the present disclosure.

As illustrated in FIG. 3, the transistor device cell 100.1 includes a semiconductor structure 102 on a substrate 104. The transistor device cell 100.2 also includes a semiconductor structure 102 on a substrate 104. The transistor device cell 100.1 includes a first source contact 122.1, a first drain contact 124.1, and a first gate contact 126.1. The transistor device cell 100.2 includes a second source contact 122.1, a second drain contact 124.2, and a second gate contact 126.2. In some embodiments, the transistor device cells 100.1, 100.2 may share a contact, such as a source contact.

The semiconductor device 134 includes isolation implant region(s) 132 between regions of the semiconductor device 134. For instance, the semiconductor device 134 includes an isolation implant region 132 between the first region 140.1 associated with the first transistor device cell 100.1 and the second region 140.2 associated with the second transistor device cell 100.2. According to example aspects of the present disclosure, the isolation implant region(s) 132 extend to a depth Id in the semiconductor structure 102 sufficient to provide electrical isolation between regions of the semiconductor device 134, such as between the first region 140.1 and the second region 140.2. In some embodiments, the depth Id may be about 500 Angstroms or greater, such as about 750 Angstroms or greater, such as in a range of about 500 Angstroms to about 5 microns, such as about 1000 Angstroms to about 2 microns, such as about 1000 Angstroms to about 2500 Angstroms.

As further shown in FIG. 3, the semiconductor structure 102 includes a first surface 102A and a second surface 102B opposite the first surface 102A. The second surface 102B is a planar surface across the first region 140.1 and the second region 140.2. Moreover, the second surface 102B is continuously planar across the first region 140.1, second region 140.2, and isolation implant regions 132 separating the first region 140.1 and 140.2. There are no recesses in the surface 102B of the semiconductor structure 102 in the area proximate the isolation implant regions 132.

FIG. 2 depicts a close up of an example isolation implant region 132. In the example of FIG. 2, the isolation implant region 132 includes a distribution of implanted dopants extending into the buffer layer 110 (e.g., an iron doped buffer layer 110). The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³. In some examples, the peak dopant concentration may be located in the isolation implant region 132 at a location proximate an interface between the barrier layer 112 and the channel layer 114. For instance, in the example of FIG. 2, the peak dopant concentration in the isolation implant region 132 may be in a region 135 within 250 Angstroms or less of the interface between the barrier layer 112 and the channel layer 114. This can serve to provide enhanced electrical isolation at a location proximate the 2DEG 115.

In some examples, the peak dopant concentration may be at a location buried deep within the semiconductor structure, such as at a depth in a range of about 500 Angstroms to about 1750 Angstroms beneath a surface of the semiconductor structure 102, such as in a range of about 750 Angstroms to about 1500 Angstroms beneath a surface of the semiconductor structure 102.

The peak dopant concentration may be in different regions within the isolation implant region 132. For instance, the peak dopant concentration may in region 137 closer to a surface of the semiconductor structure 102. The distribution of dopants may vary as a function of depth within the isolation implant region 132. In some examples, the distribution of dopants may have spikes or peaks with in region 135 and/or region 137 with the dopant concentration being less in other regions of the isolation implant region 132. In some examples, the dopant concentration may be nearly uniform throughout the isolation implant region 132.

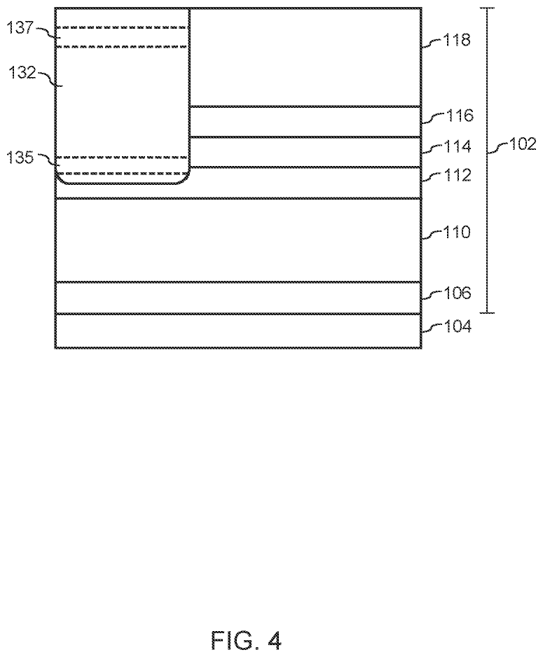

The isolation implant region 132 may extend to other depths within the semiconductor structure 102 without deviating from the scope of the present disclosure. For example, FIG. 4 depicts an example isolation implant region 132 that extends at least to the barrier layer 114 of the semiconductor structure 102. In the example of FIG. 4, the isolation implant region 132 includes a distribution of implanted dopants extending into the barrier layer 112. The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³. In some examples, the peak dopant concentration may be located in the isolation implant region 132 at a location proximate an interface between the barrier layer 112 and the channel layer 114. For instance, in the example of FIG. 4, the peak distribution of dopants in the isolation implant region 132 may be in a region 135 within 250 Angstroms or less of the interface between the barrier layer 112 and the channel layer 114. The peak dopant concentration may be in different regions within the isolation implant region 132 of FIG. 4. For instance, the peak dopant concentration may in region 137 closer to a surface of the semiconductor structure 102.

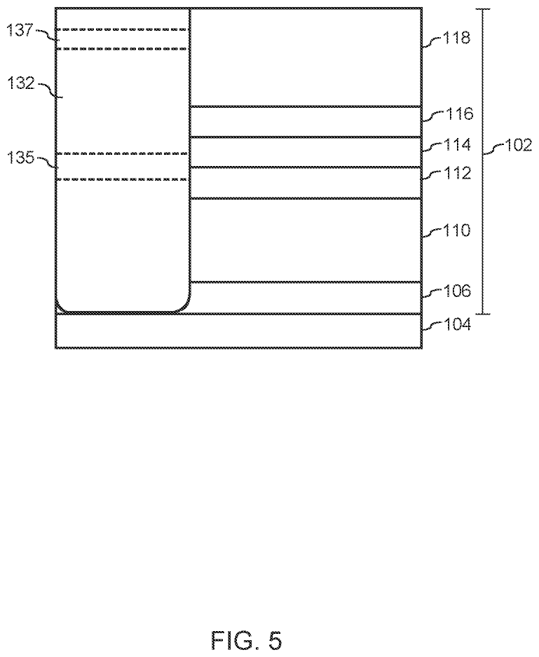

As another example, FIG. 5 depicts an example isolation implant region 132 that extends to an interface between the semiconductor structure 102 and the substrate 104. In the example of FIG. 5, the isolation implant region 132 includes a distribution of implanted dopants extending to the interface between the semiconductor structure 102 and the substrate 104. The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³. In some examples, the peak dopant concentration may be located in the isolation implant region 132 at a location proximate an interface between the barrier layer 112 and the channel layer 114. For instance, in the example of FIG. 5, the peak distribution of dopants in the isolation implant region 132 may be in a region 135 within 250 Angstroms or less of the interface between the barrier layer 112 and the channel layer 114. The peak dopant concentration may be in different regions within the isolation implant region 132 of FIG. 5. For instance, the peak dopant concentration may in region 137 closer to a surface of the semiconductor structure 102.

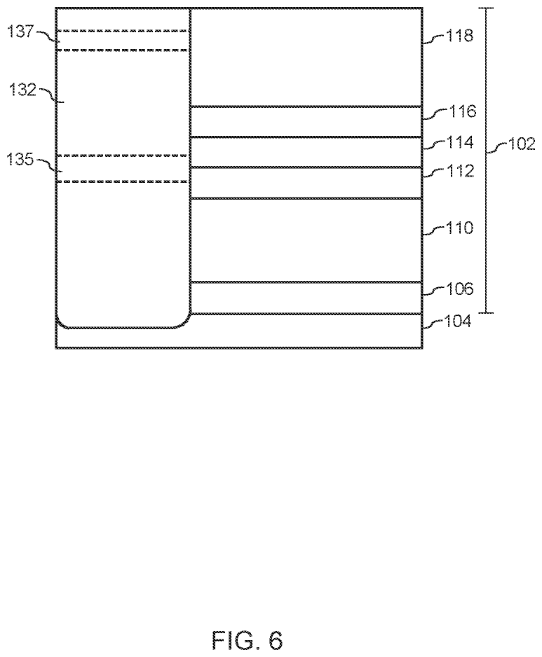

As another example, FIG. 6 depicts an example isolation implant region 132 that extends into the substrate 104. In the example of FIG. 6, the isolation implant region 132 includes a distribution of implanted dopants extending to into the substrate 104. The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³. In some examples, the peak dopant concentration may be located in the isolation implant region 132 at a location proximate an interface between the barrier layer 112 and the channel layer 114. For instance, in the example of FIG. 6, the peak distribution of dopants in the isolation implant region 132 may be in a region 135 within 250 Angstroms or less of the interface between the barrier layer 112 and the channel layer 114. The peak dopant concentration may be in different regions within the isolation implant region 132 of FIG. 6. For instance, the peak dopant concentration may in region 137 closer to a surface of the semiconductor structure 102.

In each of the example isolation implant regions 132 described in FIGS. 4-6, the distribution of dopants may vary as a function of depth within the isolation implant region 132. In some examples, the distribution of dopants spikes or peaks within region 135 and/or region 137 with the dopant concentration being less in other regions of the isolation implant region 132. In some examples, the dopant concentration may be nearly uniform throughout the isolation implant region 132.

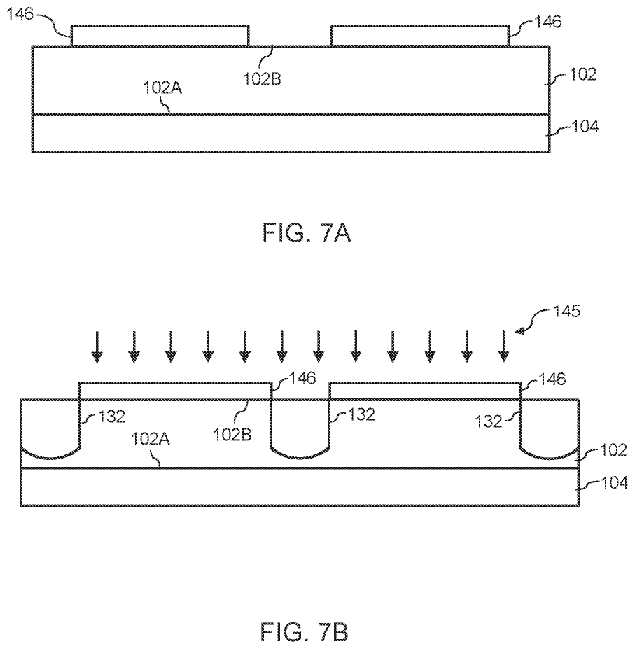

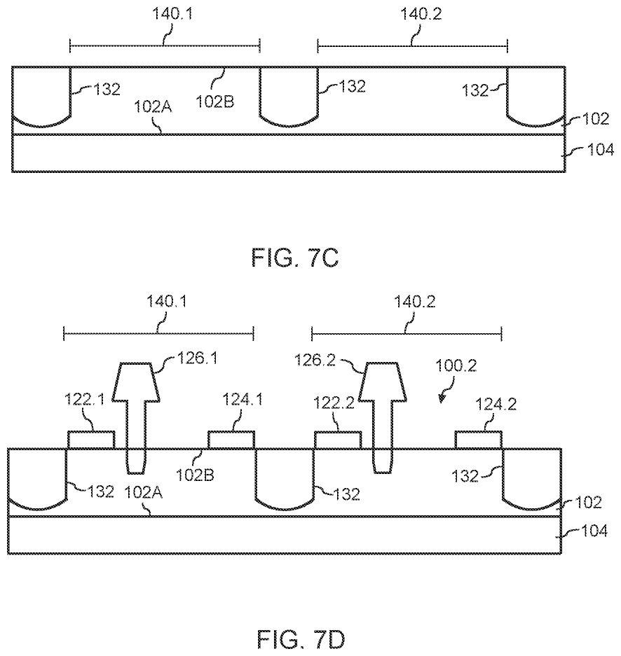

FIGS. 7A-7D depict cross-sectional views illustrating aspects of a method for forming an isolation implant region in semiconductor devices having an N-polar Group III-nitride semiconductor structure according to example embodiments of the present disclosure. FIGS. 7A-7D are intended to represent structures for identification and description and are not intended to represent the structures to physical scale. FIGS. 7A-7D depict example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In FIG. 7A, a method may include forming a semiconductor structure 102 on a substrate 104, such as a silicon carbide substrate. The semiconductor structure 102 may be an N-polar Group III-nitride semiconductor structure. The semiconductor structure 102 may be formed on a substrate 104, such as a silicon carbide substrate. The semiconductor structure 102 may be a multilayer structure an may include one or more of a nucleation layer 106, a buffer layer 110, a barrier layer 112, a channel layer 114, a first cap layer 116 and second cap layer 118. Details concerning these example layers are described above with reference to FIG. 2. The N-polar Group III-nitride semiconductor structure may have a first surface 102A on the substrate 104 and a second surface 102B opposing the first surface 102A. The second surface 102B may be a planar surface. The semiconductor structure 102 may be deposited by MOCVD or by other techniques known to those of skill in the art, such as MBE or HVPE.

As further shown in FIG. 7A, the method may include forming a mask 146 on the semiconductor structure 102. The mask 146 may include photoresist or any other suitable mask material, such as SiN and/or SiO₂. The mask 146 may have a thickness selected to block implanted dopants during an implantation process. Windows may be opened in the mask 146 to expose portions of the second surface 102B of the semiconductor structure.

As shown in FIG. 7B, the method may include performing an implantation process 148 to implant dopants into the semiconductor structure 102 to form the isolation implant regions 132. The implant conditions of the implantation process 148 may be selected such that the isolation implant region extends from the second surface 102B of the semiconductor structure 102 to a depth sufficient to provide electrical isolation between regions in the semiconductor structure 102. For instance, the implant regions 132 may extend into the semiconductor structure at depths described in the examples of FIGS. 2-6. In some examples, the implant conditions of the implantation process 148 may be selected such that the isolation implant region 132 extends to a depth of about 500 Angstroms or greater, such as about 750 Angstroms or greater, such as in a range of about 500 Angstroms to about 5 microns, such as about 1000 Angstroms to about 2 microns, such as about 1000 Angstroms to about 2500 Angstroms.

In some examples, the implant conditions of the implantation process 148 may be selected such that isolation implant regions 132 may extend into a buffer layer associated with the N-polar Group III-nitride semiconductor structure 102. In some examples, the implant conditions of the implantation process 148 may be selected such that the isolation implant regions 132 may extend into a barrier layer (e.g., a back barrier layer) associated with the N-polar Group III-nitride semiconductor structure 102.

In some examples, the implant conditions of the implantation process 148 may be selected such that the isolation implant regions 132 may extend through the N-polar Group III-nitride semiconductor structure 102 to an interface between the N-polar Group III-nitride semiconductor structure and the substrate 104. In some examples, the implant conditions of the implantation process 148 may be selected such that the isolation implant regions 132 may extend at least partially into the substrate 104.

In some examples, the implant conditions of the implantation process 148 may be selected such that isolation implant regions 132 may have a distribution of dopants. The dopants may include one or more of nitrogen, hydrogen, zirconium, magnesium, and/or oxygen. The distribution of dopants may have a peak dopant concentration. For instance, in some examples, the distribution of dopants may have a peak dopant concentration of at least about 1×10¹⁸ dopants/cm³.

In some examples, the implant conditions of the implantation process 148 may be selected such that the distribution of dopants may have a distribution profile. In some examples, the distribution profile may be nearly uniform at all depths of the isolation implant regions 132. In some examples, the distribution profile may have one or more peak regions where there is an increased dopant concentration relative to other regions in the isolation implant regions 132. In some examples, the peak dopant concentration may be located in the isolation implant regions 132 at a region near an interface between a barrier layer and a channel layer in the N-polar Group III-nitride semiconductor structure (e.g., near a 2DEG).

As shown in FIG. 7C, the method may include removing the mask 146. An activation anneal may be implemented to activate the dopants implanted into the semiconductor structure 102 to form the isolation implant regions 132. The activation anneal may be performed before or after removal of the mask 146. The isolation implant regions 132 separate a first region 140.1 of the semiconductor device from a second region 140.2 of the semiconductor device. The isolation implant regions 132 may provide electrical isolation between the first region 140.1 and the second region 140.2.

As shown in FIG. 7D, the method may include forming a electrodes on the semiconductor structure 102 to form semiconductor devices, such as transistor devices, in the respective regions 140.1 and 140.2 of the semiconductor device. For instance, the method may include forming a first source contact 122.1, a first drain contact 124.1, and a first gate contact 126.1 on the second surface 102B of the semiconductor structure 102 in the first region 140.1 to form a first transistor device. The method may include forming a second source contact 122.2, a second drain contact 124.2, and a second gate contact 126.2 on the second surface 102B of the semiconductor structure 102 in the second region 140.2 to form a second transistor device. The isolation implant regions 132 may provide electrical isolation between the first transistor device in the first region 140.1 and the second transistor device in the second region 140.2.

As further shown in FIG. 7D, the second surface 102B is a planar surface across the first region 140.1 and the second region 140.2. Moreover, the second surface 102B is continuously planar across the first region 140.1, second region 140.2, and isolation implant regions 132 separating the first region 140.1 and 140.2. There are no recesses in the surface 102B of the semiconductor structure 102B in the area proximate the isolation implant regions 132.

Example aspects of the present disclosure are set forth below. Any of the below features or examples may be used in combination with any of the embodiments or features provided in the present disclosure.

One example aspect of the present disclosure is directed to a semiconductor device. The semiconductor device may include a nitrogen-polar (N-polar) Group III-nitride semiconductor structure. The N-polar Group III-nitride semiconductor structure may have a first region and a second region. The N-polar Group III-nitride semiconductor structure may have a first surface and a second surface opposing the first surface. The second surface may be a planar surface. The semiconductor device may include an isolation implant region extending from the second surface into the N-polar Group III-nitride semiconductor structure to a depth sufficient to provide electrical isolation between the first region and the second region of the N-polar Group III-nitride semiconductor structure.

In some embodiments, the isolation implant region extends to a depth of about 500 Angstroms or greater from the second surface of the N-polar Group III-nitride semiconductor structure. In some embodiments, the isolation implant region extends to a depth of about 1000 Angstroms or greater from the second surface of the N-polar Group III-nitride semiconductor structure.

In some embodiments, the isolation implant region extends through the N-polar Group III-nitride semiconductor structure to an interface between the first surface of the N-polar Group III-nitride semiconductor structure and a substrate. In some embodiments, the isolation implant region extends from the second surface of the N-polar Group III-nitride semiconductor structure at least partially into a substrate.

In some embodiments, the isolation implant region comprises a distribution of dopants. In some embodiments, the dopants comprise one or more of nitrogen, hydrogen, zirconium, magnesium, or oxygen. In some embodiments, the distribution of dopants has a peak dopant concentration at a depth in the isolation implant region within about 250 Angstroms or less of an interface between a barrier layer and a channel layer in the N-polar Group III-nitride semiconductor structure. In some embodiments, the distribution of dopants has a peak dopant concentration at a depth in the isolation implant region of about 500 Angstroms to about 1750 Angstroms beneath a surface of the N-polar Group III-nitride semiconductor structure.

In some embodiments, the first region is associated with a first device cell and the second region is associated with a second device cell. In some embodiments, the first device cell is a first transistor device cell and the second device cell is a second transistor device cell.

In some embodiments, the first region comprises a first gate contact, a first source contact, and a first drain contact on the second surface of the N-polar Group III-nitride semiconductor structure, and the second region comprises a second gate contact, a second source contact, and a second drain contact on the second surface of the N-polar Group III-nitride semiconductor structure.

In some embodiments, the first transistor device cell is a first high electron mobility transistor device cell, and the second transistor device cell is a second high electron mobility transistor device cell.

In some embodiments, the N-polar Group III-nitride semiconductor structure has a continuously planar second surface across the first region and the second region.

In some embodiments, the N-polar Group III-nitride semiconductor structure has a nitrogen face in a growth direction of the Group III-nitride semiconductor structure.

In some embodiments, the semiconductor device further comprises a silicon carbide substrate.

In some embodiments, the semiconductor device is operable in a frequency range of about 30 GHz or greater.

Another example aspect of the present disclosure is directed to a semiconductor device. The semiconductor device may include an N-polar Group III-nitride semiconductor structure. The N-polar Group III-nitride semiconductor structure may have a first surface and a second surface opposing the first surface. The second surface may be a planar surface. The N-polar Group III-nitride semiconductor structure may include a barrier layer and a channel layer on the barrier layer. The N-polar Group III-nitride semiconductor structure may include a two-dimensional electron gas (2DEG) at an interface between the barrier layer and the channel layer. The semiconductor device may include an isolation implant region extending from the second surface of the N-polar Group III-nitride semiconductor structure at least into the channel layer.

In some embodiments, the isolation implant region extends from the second surface of the N-polar Group III-nitride semiconductor structure at least into the barrier layer.

In some embodiments, the isolation implant region extends through the N-polar Group III-nitride semiconductor structure to an interface between the first surface of the N-polar Group III-nitride semiconductor structure and a substrate. In some embodiments, the isolation implant region extends from the second surface of the N-polar Group III-nitride semiconductor structure at least partially into a substrate.

In some embodiments, the barrier layer comprises Al_{w}Ga_{1-w}N, where w is in a range of about 0.1 to about 0.4; and the channel layer comprises AlₓGa₁₋ₓN, where x is less than about 0.1. In some embodiments, the N-polar Group III-nitride semiconductor structure comprises one or more cap layers on the channel layer. In some embodiments, the one or more cap layers comprise a first cap layer and a second cap layer, wherein the first cap layer comprises Al_{y}Ga_{1-y}N, where y is in a range of about 0.1 to about 0.4, and wherein the second cap layer comprises Al_{z}Ga_{1-z}N, where w is in less than about 0.1. In some embodiments, the second cap layer has a thickness in a range of about 250 Angstroms to about 1000 Angstroms.

In some embodiments, the N-polar Group III-nitride semiconductor structure comprises a buffer layer, the barrier layer being on the buffer layer, the isolation implant region extending into the buffer layer.

In some embodiments, the isolation implant region comprises a distribution of dopants, the dopants comprising one or more of nitrogen, hydrogen, zirconium, magnesium, or oxygen. In some embodiments, the distribution of dopants has a peak dopant concentration at a depth within about 250 Angstroms or less of an interface between a channel layer and a barrier layer of the N-polar Group III-nitride semiconductor structure. In some embodiments, the distribution of dopants has a peak dopant concentration at a depth in the isolation implant region of about 500 Angstroms to about 1750 Angstroms beneath a surface of the N-polar Group III-nitride semiconductor structure.

In some embodiments, the semiconductor device comprises a gate contact, a source contact, and a drain contact on the second surface of the N-polar Group III-nitride semiconductor structure.

In some embodiments, the semiconductor device comprises an implanted region beneath one or more of the source contact and the drain contact.

In some embodiments, the isolation implant region provides electrical isolation between a first region and a second region in the Group III-nitride semiconductor structure.

In some embodiments, the N-polar Group III-nitride structure has a nitrogen face in a growth direction of the N-polar Group III-nitride semiconductor structure.

In some embodiments, the semiconductor device comprises a silicon carbide substrate.

In some embodiments, the semiconductor device is operable in a frequency range of about 30 GHz or greater.

In some embodiments, the semiconductor device comprises a high electron mobility transistor device.

Another example aspect of the present disclosure is directed to a method of forming a semiconductor device. The method may include forming an N-polar Group III-nitride semiconductor structure. The N-polar Group III-nitride semiconductor structure may have a first region and a second region. The N-polar Group III-nitride semiconductor structure may have a first surface and a second surface opposing the first surface. The method may include implanting dopants into the N-polar Group III-nitride semiconductor structure to form an isolation implant region in the semiconductor structure. The isolation implant region extends from the second surface into the N-polar Group III-nitride semiconductor structure to a depth sufficient to provide electrical isolation between the first region and the second region of the N-polar Group III-nitride semiconductor structure.

In some embodiments, the isolation implant region extends to a depth of about 500 Angstroms or greater from the second surface of the semiconductor device. In some embodiments, the isolation implant region extends to a depth of about 1000 Angstroms or greater from the second surface of the semiconductor device.

In some embodiments, the isolation implant region extends through the N-polar Group III-nitride semiconductor structure to an interface between the first surface of the N-polar Group III-nitride semiconductor structure and a substrate. In some embodiments, the isolation implant region extends from the second surface of the N-polar Group III-nitride semiconductor structure at least partially into a substrate.

In some embodiments, forming the N-polar Group III-nitride semiconductor structure comprises forming a barrier layer and forming a channel layer on the barrier layer. In some embodiments, the barrier layer comprises Al_{w}Ga_{1-w}N, where w is in a range of about 0.1 to about 0.4; and wherein the channel layer comprises AlₓGa₁₋ₓN, where x is less than about 0.1. In some embodiments, the isolation implant region extends into the barrier layer.

In some embodiments, forming the N-polar Group III-nitride semiconductor structure comprising forming one or more cap layers on the channel layer. In some embodiments, forming the one or more cap layers on the channel layer comprises forming a first cap layer on the channel layer, wherein the first cap layer comprises Al_{y}Ga_{1-y}N, where y is in a range of about 0.1 to about 0.4; and forming a second cap layer on the first cap layer, wherein the second cap layer comprises Al_{z}Ga_{1-z}N, where w is in less than about 0.1. In some embodiments, the second cap layer has a thickness in a range of about 250 Angstroms to about 1000 Angstroms.

In some embodiments, the first region is associated with a first device cell and the second region is associated with a second device cell. In some embodiments, the first device cell is associated with a first transistor device cell and the second device cell is associated with a second transistor device cell.

In some embodiments, the method comprises forming a first gate contact, a first source contact, and a first drain contact on the second surface of the N-polar Group III-nitride semiconductor structure in the first region, and forming a second gate contact, a second source contact, and a second drain contact on the second surface of the N-polar Group III-nitride semiconductor structure in the second region.

In some embodiments, the isolation implant region comprises a distribution of dopants. In some embodiments, the dopants comprise one or more of nitrogen, hydrogen, zirconium, magnesium, or oxygen. In some embodiments, the distribution of dopants has a peak dopant concentration at a depth within about 250 Angstroms or less of an interface between a channel layer and a barrier layer of the N-polar Group III-nitride semiconductor structure. In some embodiments, the distribution of dopants has a peak dopant concentration at a depth in the isolation implant region of about 500 Angstroms to about 1750 Angstroms beneath a surface of the N-polar Group III-nitride semiconductor structure.

In some embodiments, the N-polar Group III-nitride structure has a nitrogen face in a growth direction of the N-polar Group III-nitride semiconductor structure.

In some embodiments, the N-polar Group III-nitride structure is formed on a silicon carbide substrate.

In some embodiments, the semiconductor device is operable in a frequency range of about 30 GHz or greater.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a nitrogen-polar (N-polar) Group III-nitride semiconductor structure, the N-polar Group III-nitride semiconductor structure having a first region and a second region, the N-polar Group III-nitride semiconductor structure having a first surface and a second surface opposing the first surface, the second surface being a planar surface; and
an isolation implant region extending from the second surface into the N-polar Group III-nitride semiconductor structure to a depth sufficient to provide electrical isolation between the first region and the second region of the N-polar Group III-nitride semiconductor structure.

2. The semiconductor device of claim 1, wherein the isolation implant region extends to a depth of about 500 Angstroms or greater from the second surface of the N-polar Group III-nitride semiconductor structure.

3. The semiconductor device of claim 1, wherein the isolation implant region extends to a depth of about 1000 Angstroms or greater from the second surface of the N-polar Group III-nitride semiconductor structure.

4. The semiconductor device of claim 1, wherein the isolation implant region extends through the N-polar Group III-nitride semiconductor structure to an interface between the first surface of the N-polar Group III-nitride semiconductor structure and a substrate.

5. The semiconductor device of claim 1, wherein the isolation implant region extends from the second surface of the N-polar Group III-nitride semiconductor structure at least partially into a substrate.

6. The semiconductor device of claim 1, wherein the isolation implant region comprises a distribution of dopants, wherein the dopants comprise one or more of nitrogen, hydrogen, zirconium, magnesium, or oxygen.

7. (canceled)

8. The semiconductor device of claim 6, wherein the distribution of dopants has a peak dopant concentration at a depth in the isolation implant region within about 250 Angstroms or less of an interface between a barrier layer and a channel layer in the N-polar Group III-nitride semiconductor structure.

9. The semiconductor device of claim 6, wherein the distribution of dopants has a peak dopant concentration at a depth in the isolation implant region of about 500 Angstroms to about 1750 Angstroms beneath the second surface of the N-polar Group III-nitride semiconductor structure.

10. The semiconductor device of claim 1, wherein the first region is associated with a first device cell and the second region is associated with a second device cell.

11. The semiconductor device of claim 10, wherein the first device cell is a first transistor device cell and the second device cell is a second transistor device cell.

12. The semiconductor device of claim 11, wherein the first region comprises a first gate contact, a first source contact, and a first drain contact on the second surface of the N-polar Group III-nitride semiconductor structure, wherein the second region comprises a second gate contact, a second source contact, and a second drain contact on the second surface of the N-polar Group III-nitride semiconductor structure.

13. The semiconductor device of claim 11, wherein the first transistor device cell is a first high electron mobility transistor device cell, and the second transistor device cell is a second high electron mobility transistor device cell.

14. The semiconductor device of claim 1, wherein the N-polar Group III-nitride semiconductor structure has a continuously planar second surface across the first region and the second region.

15. The semiconductor device of claim 1, wherein the N-polar Group III-nitride semiconductor structure has a nitrogen face in a growth direction of the Group III-nitride semiconductor structure.

16. The semiconductor device of claim 1, wherein the semiconductor device further comprises a silicon carbide substrate.

17. The semiconductor device of claim 1, wherein the semiconductor device is operable in a frequency range of about 30 GHz or greater.

18. A semiconductor device, comprising:
a nitrogen-polar (N-polar) N-polar Group III-nitride semiconductor structure, the N-polar Group III-nitride semiconductor structure having a first surface and a second surface opposing the first surface, the second surface being a planar surface, wherein the N-polar Group III-nitride semiconductor structure comprises:
a barrier layer; and
a channel layer on the barrier layer;
a two-dimensional electron gas (2DEG) at an interface between the barrier layer and the channel layer; and
an isolation implant region extending from the second surface of the N-polar Group III-nitride semiconductor structure at least into the channel layer.

19. The semiconductor device of claim 18, wherein the isolation implant region extends from the second surface of the N-polar Group III-nitride semiconductor structure at least into the barrier layer.

20. The semiconductor device of claim 18, wherein the isolation implant region extends through the N-polar Group III-nitride semiconductor structure to an interface between the first surface of the N-polar Group III-nitride semiconductor structure and a substrate.

21.-36. (canceled)

37. A method of forming a semiconductor device, comprising:
forming a nitrogen-polar (N-polar) Group III-nitride semiconductor structure, the N-polar Group III-nitride semiconductor structure having a first region and a second region, the N-polar Group III-nitride semiconductor structure having a first surface and an opposing second surface, the second surface being a planar surface; and
implanting dopants into the N-polar Group III-nitride semiconductor structure to form an isolation implant region in the semiconductor structure, the isolation implant region extending from the second surface into the N-polar Group III-nitride semiconductor structure to a depth sufficient to provide electrical isolation between the first region and the second region of the N-polar Group III-nitride semiconductor structure.

38.-57. (canceled)
